(19) United States
(12) Patent Application Publication
(10) Pub. No.: US 2011/0200749 A1
(43) Pub. Date: Aug. 18, 2011

(54) FILM DEPOSITION APPARATUS AND METHOD

(76) Inventors: Kunihiko SUZUKI, Shizuoka (JP); Masayoshi Yajima, Kanagawa (JP)

(21) Appl. No.: 13/020,188

(22) Filed: Feb. 3, 2011

(30) Foreign Application Priority Data
Feb. 17, 2010 (JP) 2010-032742

(51) Int. Cl. C23C 16/458; C23C 16/455; C23C 16/46

(52) U.S. Cl. 427/255.5; 118/730

(57) ABSTRACT

A chamber includes at its upper section a gas inlet from which to introduce a deposition gas. The inner walls of the chamber are covered by a cylindrical liner, and the chamber houses a susceptor assembly on which to place a semiconductor substrate. The liner includes a barrel section inside which the susceptor assembly is placed; a head section that is located right below the gas inlet and smaller in horizontal cross-sectional area than the barrel section; and a stepped section that connects the barrel section and the head section. The susceptor assembly is formed by fixing a ring plate to a susceptor via support posts. The ring plate covers the periphery of the stepped section of the liner. By the deposition gas flowing in a downward direction from the gas inlet into the chamber, a crystalline film is formed on the substrate positioned on the susceptor assembly.

### BACKGROUND OF THE INVENTION

1. Field of the Invention

The present invention relates to a film deposition apparatus and a film deposition method.

2. Background Art

Epitaxy or epitaxial growth is often employed in manufacturing such semiconductor devices that require relatively thick crystalline films. Examples of these devices include power semiconductor devices such as insulated-gate bipolar transistors (IGBTs) and the like.

Vapor-phase epitaxy, a form of epitaxial growth, requires that the film deposition chamber in which a semiconductor substrate (e.g., a silicon wafer) has been placed be kept at atmospheric pressure (0.1 MPa or 760 Torr) or lower if silicon (Si) crystals are to be grown on the substrate to obtain an Si monocrystalline substrate.

After the substrate has been heated to a given temperature, the chamber is supplied with a deposition gas, which is typically formed by mixing a silicon source gas with a boron-based dopant gas (e.g., diborane: B₂H₆), a phosphorus-based dopant gas (e.g., phosphine: PH₃), or an arsenic-based dopant gas (e.g., arsine: AsH₃). When the deposition gas is supplied onto the surface of the heated substrate, its silicon source gas undergoes thermal decomposition or hydrogen reduction, thereby depositing a boron-, phosphorus-, or arsenic-doped film on the substrate's surface.

Manufacturing large-thickness epitaxial wafers at a high yield rate requires increasing the film deposition speed, which involves consecutively supplying deposition gas onto the surface of a wafer after the wafer has been uniformly heated. Thus, conventional deposition apparatuses are typically designed to rotate a wafer at high speed, thereby increasing the speed of epitaxial growth.

Another approach involves improving the efficiency of deposition gas supply. Under this approach, a deposition apparatus is designed so that deposition gas is efficiently directed toward the surface of a wafer placed inside the chamber.

Japanese Patent Laid-Open No. 2009-231587, for example, discloses a semiconductor manufacturing apparatus that includes a flow straightening vane and a ring-shaped fin. The flow straightening vane is installed inside the chamber and is designed to make the flow of a deposition gas laminar and direct the laminar gas flow toward a semiconductor substrate supported by a holder. The ring-shaped fin is located below the flow straightening vane, and its lower-end diameter is larger than its upper-end diameter. This fin is designed to direct the gas downward that has flowed over and away from the substrate. The above structure allows for efficient use of the deposition gas.

FIG. 3 is a cross section of a typical deposition apparatus used for epitaxial growth. The deposition apparatus 200 shown in FIG. 3 allows for high-speed rotation of a semiconductor substrate and efficient use of deposition gas.

As illustrated in FIG. 3, the deposition apparatus 200 includes the following components: a chamber 201 having upper and lower sections; a hollow, cylindrical liner 202 located inside the chamber 201 to protect its inner walls; coolant passageways 203a and 203b through which coolant water flows to cool the chamber 201; a gas inlet 204 from which a deposition gas 225 is introduced; gas outlets 205 from which to discharge the deposition gas 225 after use; a semiconductor substrate 206 (e.g., a wafer) on which vapor-phase epitaxy is performed; a susceptor 207 for supporting the substrate 206; a heater 208, fixed to a support (not illustrated), for heating the substrate 206; flanges 209 for connecting the upper and lower sections of the chamber 201; a packing material 210 for sealing the flanges 209; flanges 211 used for connection of the gas outlets 205 to pipes; and packing materials 212 for sealing the flanges 211.

The liner 202 is typically formed from quartz. The liner 202 includes a head section 231, and an upper open portion of the head section 231 is provided with a shower plate 220 which serves as a flow straightening vane for uniformly supplying the deposition gas 225 across the top surface of the substrate 206.

A rotary shaft 222 is located at a bottom section of the chamber 201 and extends upwardly into the chamber 201. Fixed to the upper end of the rotary shaft 222 is a rotary drum 223 on which the susceptor 207 is placed. Thus, the susceptor 207 is positioned inside the chamber 201 such that the susceptor 207 rotates above the heater 208.

Supported by the susceptor 207, the substrate 206 is placed inside the chamber 201. The heater 208 is used to heat the substrate 206 up to more than 1,000 degrees Celsius while a rotating mechanism, not illustrated, rotates the rotary shaft 222, hence also rotating the substrate 206 placed on the susceptor 207. After the substrate 206 has been heated sufficiently, the deposition gas 225, which includes a reactive gas, is fed from the gas inlet 204 into the chamber 201 while the rotation of the substrate 206 continues; the gas 225 flows past the through-holes 221 of the shower plate 220 and moves toward the top surface of the substrate 206.

The deposition gas 225 undergoes thermal decomposition or hydrogen reduction over the top surface of the substrate 206, thereby depositing a crystalline film thereon. By-product gases, or part of the deposition gas 225 that has not been used for the vapor-phase epitaxy and has changed in its properties is discharged from the gas outlets 205 located at the bottom of the chamber 201.

The deposition apparatus 200 performs epitaxy while rotating the substrate 206 at high speed, and its film deposition speed is high because the deposition gas 225 is consecutively supplied onto the top surface of the substrate 206 after the substrate 206 has been uniformly heated.

The through-holes 221 are arranged in the shower plate 220 such that each of the through-holes 221 is above a particular area of the substrate 206; the purpose is to uniformly supply the deposition gas 225 across the substrate 206.

The liner 202 also includes a barrel section 230. The head section 231, which supports the shower plate 220, is smaller in inner diameter than the barrel section 230. That is, the liner 202 is designed so that the shower plate 220 is supported at its upper section (i.e., by the head section 231) and such that the head section 231 through which the deposition gas 225 flows is smaller in inner diameter and horizontal cross-sectional area than the barrel section 230 inside which the substrate 206 is placed.

The above structure of the liner 202 prevents the deposition gas 225 from diffusing in an undesirable manner after flowing past the through-holes 221 of the shower plate 220. That is, the deposition gas 225 can be directed efficiently onto the top surface of the substrate 206, which leads to efficient use of the deposition gas 225.

As mentioned above, when the deposition gas 225 is supplied from the gas inlet 204 into the chamber 201, the gas 225 flows downward inside the head section 231 and moves toward the top surface of the substrate 206 in an efficient manner. See FIG. 3 to note that the space between the periphery of the substrate 206 and the liner 202 is narrow so that the deposition gas 225 can flow over the substrate 206 in the form of a laminar flow. More precisely, the liner 202 further includes a stepped section 232 that connects the head section 231 and the barrel section 230, and the space between a corner 234 of this stepped section 232 and the periphery of the substrate 206 is made narrow.

It is known, however, that the above mentioned narrow space is prone to the following problem: radiant heat from the heater 208 may not only heat the substrate 206 but the other components of the deposition apparatus 200 as well. This unwanted temperature increase is especially noticeable in areas close to the high-temperature components such as the substrate 206 and the heater 208.

Thus, the stepped section 232, especially the corner 234 of the liner 202, is heated to a very high temperature because of its proximity to the substrate 206 and the heater 208.

FIG. 4 is an enlarged view of the deposition apparatus 200 of FIG. 3.

When coming into contact with an excessively heated portion of the liner 202, the deposition gas 225 may undergo thermal decomposition or hydrogen reduction as if the gas 225 came into contact with the top surface of the substrate 206. As illustrated in FIG. 4, the result would be the formation of silicon crystals 235 on the corner 234 of the stepped section 232.

Such silicon crystal formation will further narrow the space between the corner 234 and the periphery of the substrate 206, which acts as a passageway for the deposition gas 225. This may in turn change the flow of the deposition gas 225 over the surface of the substrate 206, resulting in formation of an uneven crystalline film on the substrate 206.

The silicon crystals 235 are substantially the same in property as the film to be deposited on the surface of the substrate 206, and the formation of the silicon crystals 235 will result in an obstruction in this area.

The silicon crystals 235 obstructing the liner 202 can be removed by, for example, hydrofluoric acid cleaning, but the complete removal of the silicon crystals 235 is not easy. It is also likely that part of the silicon crystals 235 may come off and accumulate as dust particles inside the chamber 201 if the deposition apparatus 200 is used over and over, which involves repetitions of temperature increases and decreases inside the chamber 201. Those dust particles may contaminate films to be deposited on substrates during subsequent vapor-phase epitaxial processes and can be a factor that lowers product quality.

For the purpose of continuously operating the deposition apparatus 200, it is therefore necessary to remove the silicon crystals 235 and keep the chamber 201 free from them. This requires that the operation of the deposition apparatus 200 be stopped periodically for the maintenance of the chamber 201.

The maintenance, however, is often a time-consuming process as it involves not only cleaning of the chamber 201 but preparation for the restart operation. For example, it takes a considerable amount of time and effort to reassemble the chamber 201 after cleaning, while at the same time preventing the cleaned chamber 201 from being contaminated by dust particles in ambient air and then adjusting the chamber 201 to a given degree of vacuum.

Since the deposition apparatus 200 requires periodical maintenance for removing dust particles, the operating rate of the apparatus 200 cannot be increased beyond a particular point. As above, problems with the deposition apparatus 200 include concern about the quality of semiconductor substrates to be manufactured and a decrease in the operating rate due to maintenance.

In view of the above, an object of the present invention is to provide a film deposition apparatus that does not decrease the quality of semiconductor substrates to be manufactured even if unwanted by-products may result during vapor-phase epitaxy from a deposition gas fed into its chamber. Further, another object of the present invention is to provide a film deposition apparatus that has a higher operating rate than conventional apparatuses, and to provide a film deposition method using the same apparatus.

Other advantages and challenges of the present invention are apparent from the following description.

### SUMMARY OF THE INVENTION

The present invention relates to an apparatus and method used for film deposition. The apparatus comprising: a chamber; a gas inlet for supplying a deposition gas into the chamber; a gas outlet located at a bottom section of the chamber; a cylindrical liner for covering inner surfaces of the chamber, the liner including: a barrel section; a head section having an opening, the head section being smaller in horizontal cross-sectional area than the barrel section; and a stepped section for connecting the barrel section and the head section; a shower plate 20 which operates as a flow straightening vane, located at the opening of the head section of the liner, for producing a laminar flow of the deposition gas supplied into the chamber; a rotary shaft located at a bottom section of the chamber and extending upwardly into the barrel section of the liner; a rotary drum connected to an upper end of the rotary shaft; and a susceptor assembly on which to place a substrate, the susceptor assembly being supported by the rotary drum inside the barrel section, wherein the susceptor assembly includes: a susceptor on which to place the substrate, the susceptor being supported by the rotary drum; support posts attached to the susceptor; and a ring plate fixed to the support posts so that the ring plate is spaced apart from the susceptor, and wherein the ring plate covers a peripheral area of the stepped section of the liner with the susceptor assembly being supported by the rotary drum.

In another embodiment of this invention; A deposition method for supplying a deposition gas from a top section of a chamber toward a substrate placed on a susceptor assembly supported by a rotary drum while heating the substrate, thereby depositing a particular film on the substrate, wherein the chamber houses a cylindrical liner that includes: a barrel section inside which the susceptor assembly is placed; a head section smaller in horizontal cross-sectional area than the barrel section; and a stepped section for connecting the barrel section and the head section, wherein the susceptor assembly includes: a susceptor on which to place the substrate; support posts attached to the susceptor; and a ring plate fixed to the support posts such that the ring plate is spaced apart from the susceptor, the ring plate being adapted to cover a peripheral area of the stepped section of the liner, and wherein the deposition gas flows inside the head section of the liner and moves in a downward direction toward the substrate.

### BRIEF DESCRIPTION OF THE DRAWINGS

FIG. 1 is a cross sectional diagram illustrating a deposition apparatus according to an embodiment of the present invention.

FIG. 2 is an enlarged view of the deposition apparatus in the present invention.

FIG. 3 is a cross section of a typical deposition apparatus used for epitaxial growth.

FIG. 4 is an enlarged view of a typical deposition apparatus used for epitaxial growth.

### DETAILED DESCRIPTION OF THE EMBODIMENTS

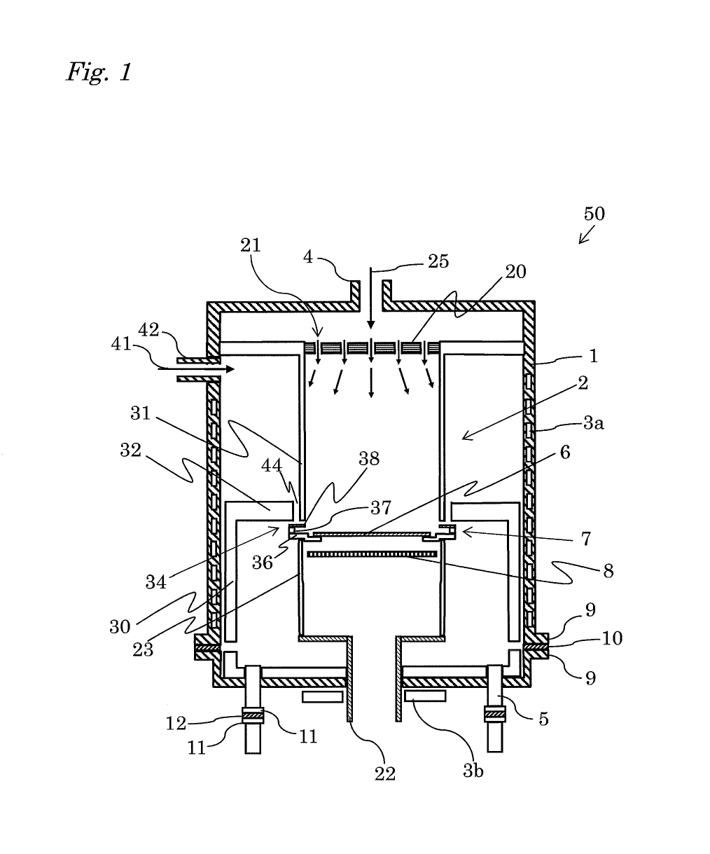

FIG. 1 is a cross sectional diagram illustrating a deposition apparatus according to an embodiment of the present invention.

The deposition apparatus 50 of FIG. 1 comprises of the following components: a film deposition chamber 1 having upper and lower sections; a hollow, cylindrical liner 2 located inside the chamber 1 to protect its inner walls; coolant passageways 3a and 3b through which coolant, for example, water flows to cool the chamber 1; a gas inlet 4 from which to introduce a deposition gas 25; gas outlets 5 from which to discharge the deposition gas 25 after use; a susceptor assembly 7 on which to place a semiconductor substrate 6 such as a silicon wafer or the like; a heater 8, fixed to a support (not illustrated) for heating the substrate 6; flanges 9 for connecting the upper and lower sections of the chamber 1; a packing material 10 for sealing the flanges 9; flanges 11 used for connection of the gas outlets 5 to pipes; and packing material 12 for sealing the flanges 11.

The chamber 1 has a purge gas inlet 42 located at an upper section of its side wall so that a purge gas 41, for example, inert gas such as an argon (Ar) gas or the like, can be fed into the space between the inner walls of the chamber 1 and the outer walls of the liner 2.

The substrate 6 is placed on the susceptor assembly 7 so that vapor-phase epitaxy can be performed on the top surface of the substrate 6. The susceptor assembly 7 is supported by a rotary drum 23 which is connected to a rotating mechanism, not illustrated, via a rotary shaft 22.

The rotary shaft 22 is located at the bottom of the chamber 1 and extends upwardly into the chamber 1. Fixed to the upper end of the rotary shaft 22 is the rotary drum 23 on which the susceptor assembly 7 is placed. Thus, the susceptor assembly 7 is positioned inside the chamber 1 such that the assembly 7 rotates above the heater 8. During vapor-phase deposition, the susceptor assembly 7 is rotated at high speed, thereby also rotating the substrate 6 positioned on the assembly 7 at high speed.

As stated above, the packing materials 10 and 12 are used for sealing the flanges 9 of the chamber 1 and the flanges 11 of the gas outlets 5, respectively. The packing materials 10 and 12 are formed of fluorine rubber and can withstand a temperature of up to 300 degrees Celsius or thereabout. With the coolant passageways 3a and 3b cooling the chamber 1, it is possible to cool the packing materials 10 and 12 as well and prevent them from deteriorating due to heat.

The deposition apparatus 50 is designed to heat the substrate 6 placed on the susceptor assembly 7 up to more than 1,000 degrees Celsius with the use of the heater 8 while rotating the susceptor assembly 7 and hence the substrate 6 as well (by a rotating mechanism not shown). After the substrate 6 has been heated sufficiently, the deposition gas 25, which includes a reactive gas, is fed from the gas inlet 4 into the chamber 1 while the rotation of the substrate 6 continues; the gas 25 flows past the through-holes 21 of a shower plate 20, described later, and moves toward the top surface of the substrate 6.

The purge gas 41 is also supplied from the purge gas inlet 42 located at an upper section of a side wall of the chamber 1.

When the deposition gas 25 reaches the surface of the substrate 6, the gas 25 undergoes thermal decomposition or hydrogen reduction, thereby depositing a crystalline film on the surface of the substrate 6. By-product gases, or part of the deposition gas 25 that has not been used for the vapor-phase epitaxy and has changed in its properties, are discharged, together with the purge gas 41, from the gas outlets 5 located at the bottom of the chamber 1.

The deposition apparatus 50 performs epitaxy while rotating the substrate 6 at high speed, and its film deposition speed is high because the deposition gas 25 is supplied onto the top surface of the substrate 6 after the substrate 6 has been uniformly heated.

The main components of the deposition apparatus 50 will now be described in detail.

The liner 2 is formed from quartz. The liner 2 includes a head section 31, and an upper open portion of the head section 31 is provided with the shower plate 20 which serves as a flow straightening vane for uniformly supplying the deposition gas 25 across the top surface of the substrate 6. The shower plate 20 includes the through-holes 21 through which the deposition gas 25 passes.

The through-holes 21 are arranged in the shower plate 20 such that each of the through-holes 21 is above a particular area of the substrate 6; the purpose is to uniformly supply the deposition gas 25 across the substrate 6.

The reason the liner 2 is provided is that the walls of the chamber 1 are formed of stainless steel, as is common to typical deposition apparatuses. That is, the liner 2 is provided to cover all the inner stainless-steel surfaces of the chamber 1 so that they will not be exposed to vapor-phase epitaxy. This prevents particle or metal contamination of the substrate 6 during vapor-phase epitaxy as well as corrosion of the inner stainless-steel surfaces of the chamber 1.

In addition to the head section 31 which supports the shower plate 20, the liner 2 also includes a barrel section 30 inside which the susceptor assembly 7 and the substrate 6 are placed for vapor-phase epitaxy. The head section 31 is smaller in inner diameter than the barrel section 30; thus, the head section 31 is smaller in horizontal cross-sectional area than the barrel section 30.

The reason the head section 31 of the liner 2 is smaller in horizontal cross-sectional area is that the head section 31 is designed to support the shower plate 20 at its upper open portion and to serve as a passageway for directing the deposition gas 25 that has passed through the shower plate 20 toward the substrate 6 placed inside the barrel section 30.

The inner diameter of the head section 31 is determined based on the positions of the through-holes 21 of the shower plate 20 and on the size of the substrate 6. Accordingly, after flowing past the through-holes 21 of the shower plate 20, the deposition gas 25 can flow straight down to the top surface of the substrate 6 without diffusing, which leads to efficient use of the deposition gas 25. The thus-constructed liner 2 allows efficient vapor-phase epitaxy over the surface of the substrate 6.

The liner 2 further includes a stepped section 32 that connects the barrel section 30 and the head section 31, and through-holes 44 are formed near the joint between the stepped section 32 and the head section 31, that is, near a corner 34 of the stepped section 32. The through-holes 44 act as passageways for the purge gas 41 which is fed from the purge gas inlet 42 into the space between the inner walls of the chamber 1 and the outer walls of the liner 2.

As above, the liner 2 comprises the barrel section 30, the head section 31, and the stepped section 32, and the through-holes 44 are formed near the corner 34 of the stepped section 32. The corner 34 of the stepped section 32 is the position where the stepped section 32 and the head section 31 are connected and from which the head section 31 extends upwardly.

As illustrated in FIG. 1, the lower surface of the corner 34 is positioned right above and close to the susceptor assembly 7 and the periphery of the substrate 6 so that the deposition gas 25 cannot diffuse in an undesirable manner.

Described below is the structure of the susceptor assembly 7 of the deposition apparatus 50.

The susceptor assembly 7 includes a ring-shaped susceptor 36 on which to place the substrate 6. The assembly 7 further includes the following components: support posts 37 that are attached to the periphery of the susceptor 36; and a ring plate 38 that is fixed to the top surfaces of the support posts 37 such that the ring plate 38 is spaced apart from the susceptor 36.

The ring plate 38 of the susceptor assembly 7 can be formed from a carbon (C) material coated with silicon carbide (SiC). Possible alternative materials include a carbon material coated with tantalum carbide (TaC) or with tungsten carbide (WC) and other thermally-resistant materials which are unlikely to cause contamination of a film to be deposited on the substrate 6.

The susceptor assembly 7 can be detached from the rotary drum 23 while the substrate 6 is positioned on the susceptor 36 of the assembly 7. Thus, the substrate 6 can be placed on the susceptor 36 outside of the deposition apparatus 50 and can then be loaded into the deposition apparatus 50 together with the susceptor assembly 7.

When the susceptor assembly 7 on which the substrate 6 has been placed is loaded into the deposition apparatus 50, the assembly 7 is attached to the rotary drum 23; thereafter, vapor-phase epitaxy can be performed on the substrate 6. After the completion of the vapor-phase epitaxy, the susceptor assembly 7 can be detached from the rotary drum 23 while the substrate 6 is positioned on the susceptor 36 of the susceptor assembly 7 so that the substrate 6 can be unloaded from the deposition apparatus 50 together with the susceptor assembly 7.

The substrate 6 can then be removed from the susceptor assembly 7 outside of the deposition apparatus 50. Thereafter, a new substrate 6 may be placed on the susceptor assembly 7 after cleaned or on a new susceptor assembly 7, followed by repetition of the above procedure.

Described next is the arrangement and function of the ring plate 38 of the susceptor assembly 7 of the deposition apparatus 50.

As stated above, the head section 31 of the liner 2 is smaller in horizontal cross-sectional area than the barrel section 30. Thus, after supplied from the gas inlet 4 into the chamber 1, the deposition gas 25 flows through the head section 31 and efficiently moves toward the surface of the substrate 6. Note here that, as is similar to the foregoing deposition apparatus 200, the space between the periphery of the substrate 6 and the liner 2 is narrow so that the deposition gas 25 can flow over the substrate 6 in the form of a laminar flow. More precisely, the space between the corner 34 of the stepped section 32 and the periphery of the substrate 6 is made narrow.

The above narrow space serves to increase the flow rate of the deposition gas 25 when it flows over the substrate 6 toward the side area surrounding the rotary drum 23. This in turn prevents the deposition gas 25 from flowing upwardly toward the head section 31 after reaching the substrate 6.

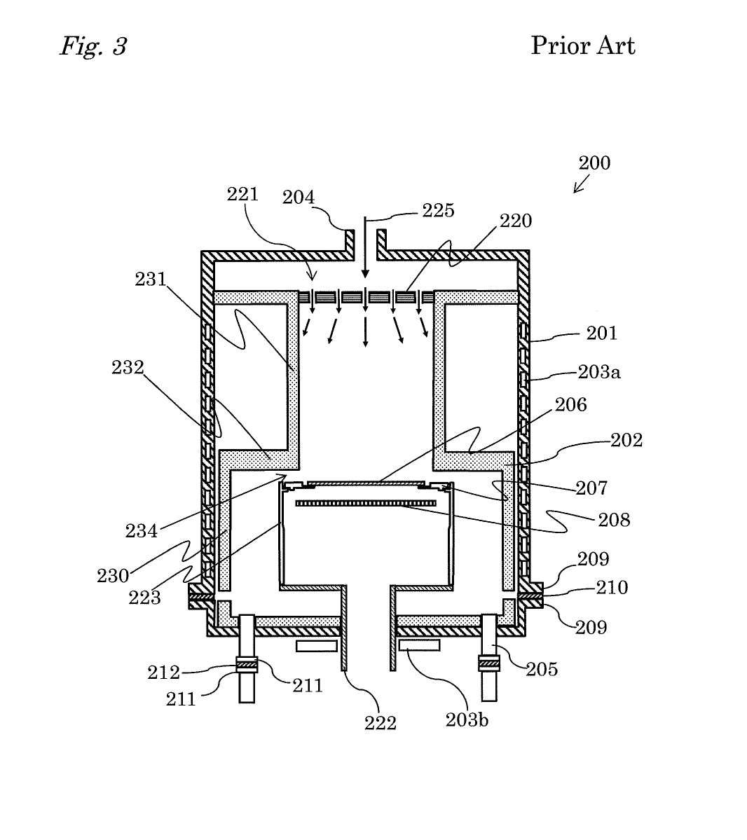

As stated earlier, the deposition apparatus 200 (see FIG. 3) is prone to the following problem due to such a narrow space: radiant heat from the heater 208 may not only heat the substrate 206 but the other components of the deposition apparatus 200 as well. This unwanted temperature increase is especially noticeable in those areas close to high-temperature components such as the substrate 206 and the heater 208.

Thus, the stepped section 232 (especially the corner 234 of the liner 202 of the deposition apparatus 200, which is close to the substrate 206 and the heater 208) may be heated to a very high temperature unless preventive measures are taken.

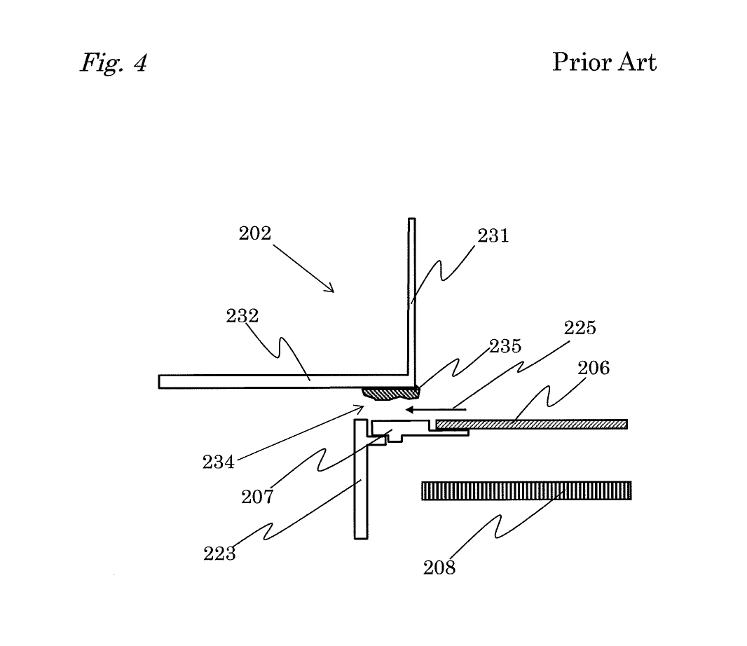

When coming into contact with an excessively heated portion of the liner 202, the deposition gas 225 may undergo thermal decomposition or hydrogen reduction as if the gas 225 came into contact with the top surface of the substrate 206. As illustrated in FIG. 4, the result would be the formation of silicon crystals 235 on the corner 234 of the stepped section 232.

Such silicon crystal formation will not only contaminate the liner 202 but further narrow the space between the corner 234 and the periphery of the substrate 206, which acts as a passageway for the deposition gas 225. This may in turn change the flow of the deposition gas 225 over the surface of the substrate 206, resulting in the formation of an uneven crystalline film on the substrate 206.

Therefore, the deposition apparatus 50 of the present invention has a ring plate 38 attached to the susceptor assembly 7. The ring plate 38 is designed to cover and protect those components close to the substrate 6 and the susceptor assembly 7, more precisely, the corner 34 of the stepped section 32 of the liner 2, so that the corner 34 may not be heated excessively.

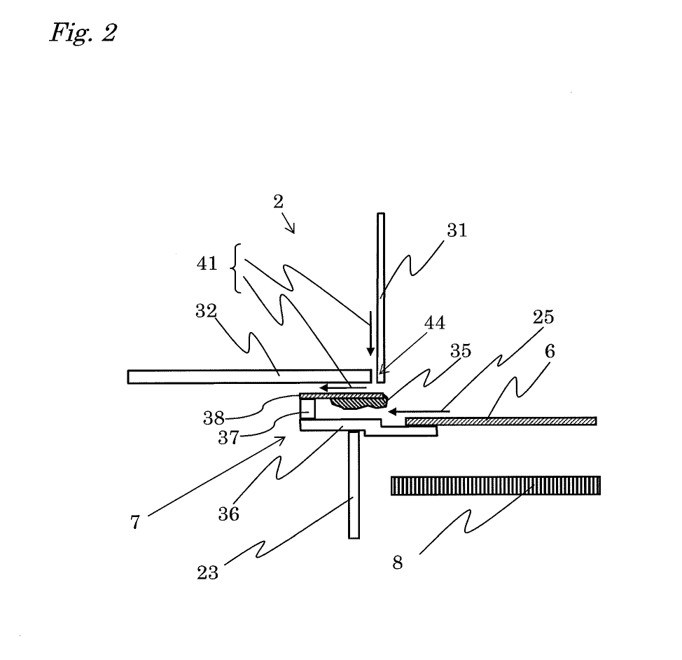

The advantages of the susceptor assembly 7 will now be discussed with reference to FIG. 2, an enlarged view of the deposition apparatus 50.

As already stated, the susceptor assembly 7 of the deposition apparatus 50 includes the following components: the susceptor 36; the support posts 37 that are attached to the periphery of the susceptor 36; and the ring plate 38 that is fixed to the top surfaces of the support posts 37 such that the ring plate 38 is spaced from the susceptor 36. When the susceptor assembly 7 is attached to the rotary drum 23 as illustrated in FIG. 2, the ring plate 38 covers and protects a length of the stepped section 32 equal to the length of the ring plate 38.

During the film deposition process a substrate 6 positioned on susceptor assembly 7 is heated, and then the deposition gas 25 undergoes thermal decomposition or hydrogen reduction on the surface of the substrate 6. Radiant heat from the heater 8 may not only heat the substrate 6 but the other components of the deposition apparatus 50 as well. This unwanted temperature increase is especially noticeable in areas close to the high-temperature components such as the substrate 6 and the heater 8.

The ring plate 38 protects the corner 34 of the stepped section 32 from the radiant heat of the heater 8 during film deposition on the substrate 6. This prevents the deposition gas 25 from undergoing thermal decomposition or hydrogen reduction at the corner 34, thus preventing silicon crystals from being attached to the corner 34. Deposition gas 25 or any gas can then exit through an area between the ring-shaped susceptor 36 and the ring plate 38.

During the film deposition, the ring plate 38 is heated to a high temperature. Thus, the deposition gas 25 undergoes thermal decomposition or hydrogen reduction beneath the lower surface of the ring plate 38 as if the gas 25 came in contact with the substrate 6. As illustrated in FIG. 2, the result is the formation of silicon crystals 35 beneath the lower surface of the ring plate 38.

As stated above, however, the susceptor assembly 7 can be detached from the rotary drum 23 while the substrate 6 is positioned on the susceptor 36 of the assembly 7. Thus, after the completion of vapor-phase epitaxy, the susceptor assembly 7 can be detached from the rotary drum 23 while the substrate 6 is positioned on the susceptor 36 so that the substrate 6 can be unloaded from the deposition apparatus 50 together with the susceptor assembly 7.

Accordingly, although the silicon crystals 35 may be formed on the ring plate 38 of the susceptor assembly 7 during film deposition on the substrate 6, the ring plate 38 can be unloaded from the deposition apparatus 50 together with the substrate 6. This means that no silicon crystals will remain inside the liner 2; that is, the silicon crystals 35 will not be formed beneath the corner 34 of the stepped section 32 of the liner 2.

The presence of the ring plate 38, therefore, serves to prevent the liner 2 from becoming obstructed. Since the ring plate 38 can be taken out of the deposition apparatus 50, it is possible to prevent part of the silicon crystals 35 from coming off and accumulating as dust particles inside the chamber 1. This in turn prevents contamination of films to be deposited on substrates during subsequent vapor-phase epitaxial processes and a decrease in product quality as well. Further advantages are that less frequent maintenance of the chamber 1 is required, the deposition apparatus 50 can be operated continuously and the operating rate of the apparatus 50 can be increased relative to conventional apparatuses.

Note that the space between the upper surface of the ring plate 38 and the lower surface of the corner 34 of the stepped section 32 also serves as a space for attachment/detachment of the susceptor assembly 7 to/from the rotary drum 23.

In order for the ring plate 38 to protect the corner 34 to the best of its ability, it is preferred that this space be as small as possible, so long as the space reduction does not affect the attachment/detachment operation.

Another advantage of the ring plate 38 is that since the ring plate 38 serves as a heat reflector to block the radiant heat of the heater 8 (especially that of the susceptor assembly 7), the ring plate 38 prevents the spread of heat away from the periphery of the substrate 6, thereby heating the substrate 6 efficiently upon film deposition. As a result, the output of the heater 8 can be reduced.

The ring plate 38 of the susceptor assembly 7 operates as a reflector of heat, especially radiant heat from the susceptor assembly 7.

The ring plate 38 thus prevents the spread of heat away from the periphery of the substrate 6, thereby heating the substrate 6 efficiently during film deposition. As a result, the output of the heater 8 can be reduced, making the deposition apparatus 50 energy-efficient.

Described next is a film deposition method according to the invention which involves the use of the above deposition apparatus 50.

First, the substrate 6 placed on the susceptor assembly 7 is heated with the use of the heater 8 while the rotating mechanism (not illustrated) rotates the substrate 6 together with the susceptor assembly 7. During the heating, coolant water flows inside the coolant passageways 3a and 3b to cool the chamber 1. After the substrate 6 has been heated sufficiently, the deposition gas 25 is supplied from the gas inlet 4 into the chamber 1 while the rotation of the substrate 6 continues. The deposition gas 25 flows past the through-holes 21 of the shower plate 20 and moves in a downward direction inside the head section 31 of the liner 2, thus reaching the substrate 6 in an efficient manner. After reaching the substrate 6, the deposition gas 25 undergoes thermal decomposition or hydrogen reduction, thereby depositing a crystalline film on the substrate 6.

The susceptor assembly 7 is supported by a rotary drum 23 which is connected to a rotating mechanism (not shown) via a rotary shaft 22.

The cylindrical liner 2 is located inside chamber 1 of the deposition apparatus 50 in order to protect its inner walls. The liner 2 includes a barrel section 30 inside which the susceptor assembly 7 is placed, the head section 31 is smaller in horizontal cross-sectional area than the barrel section 30. The Liner 2 also includes a stepped section 32 that connects the barrel section 30 and the head section 31.

As stated above, the deposition gas 25 flows through the head section 31 and efficiently moves toward the surface of the substrate 6 placed on the susceptor assembly 7. The assembly 7 further includes the following components: support posts 37 that are attached to the periphery of the susceptor 36; and a ring plate 38 that is fixed to the top surfaces of the support posts 37 so that the ring plate 38 is spaced apart from the susceptor 36.

When the susceptor assembly 7 is attached to the rotary drum 23 as illustrated in FIG. 2, the ring plate 38 covers and protects a length of the stepped section 32 equal to the length of the ring plate 38.

During the film deposition, a purge gas 41 is supplied from the purge gas inlet 42 located at an upper section of a side wall of the chamber 1. The purge gas 41 flows through the space between the inner walls of the chamber 1 and the outer walls of the liner 2 and then flows out of the space from the through-holes 44. Thereafter, the purge gas 41 flows through the space between the lower surface of the corner 34 of the stepped section 32 and the upper surface of the ring plate 38 and moves toward the side area surrounding the rotary drum 23; the purge gas 41 is eventually discharged out of the deposition apparatus 50 via the gas outlets 5.

As well as the presence of the ring plate 38, this flow of the purge gas 41 also serves to prevent the corner 34 of the stepped section 32 from being heated to a high temperature; thus, it is possible to deposit a desired crystalline film on the substrate 6 while preventing silicon crystals from being attached to the stepped section 32 or thereabout.

After the completion of the film deposition, the susceptor assembly 7 is detached from the rotary drum 23 while the substrate 6 is positioned on the susceptor 36 of the susceptor assembly 7 so that the substrate 6 can be unloaded from the deposition apparatus 50 together with the susceptor assembly 7. The substrate 6 can then be removed from the susceptor assembly 7 outside of the deposition apparatus 50. Thereafter, the susceptor assembly 7 is cleaned since the ring plate 38 may have been contaminated due to the formation of the silicon crystals 35 or the like.

A new substrate 6 is then placed on the cleaned susceptor assembly 7 or on a new susceptor assembly 7 and loaded into the chamber 1 of the deposition apparatus 50, followed by repetition of the above procedure.

It should be noted that the substrate 6 is, for example, a 300-mm-thick silicon wafer, which is commonly used for manufacturing a power semiconductor device. In that case, a film of a thickness of 10 to 100 μm is typically deposited on the silicon wafer.

Note also that the amount of the deposition gas 25 supplied to the chamber 1 is set, for example, such that H₂ (carrier gas) is supplied at 20 to 100 slm (Standard Liters per Minute), dichlorosilane (SiH₂Cl₂: reactive gas) is supplied at 50 sccm (Standard Cubic Centimeters per Minute) to 2 slm, and a small amount of dopant gas, diborane (B₂H₆) or phosphine (PH₃), is added. A diborane dopant gas results in a P-type conductive film while a phosphine dopant gas results in an N-type conductive film. Further, vapor-phase epitaxy is performed on the substrate 6 after the pressure inside the chamber 1 is adjusted to 1,333 Pa to atmospheric pressure, as an example.

During vapor-phase epitaxy, the susceptor assembly 7 is rotated at high speed, thereby also rotating the substrate 6 positioned on the assembly 7 at high speed. When a thick film is to be deposited, it is preferred the rotational speed of the substrate 6 be high (e.g., 900 rpm or thereabout).

When the above deposition conditions are used to perform vapor-phase epitaxy on the substrate 6, the heater 8 keeps the temperature of the substrate 6 at more than 1,000 degrees Celsius. For this reason, the whole inner area of the chamber 1 becomes high in temperature due to the radiant heat of the heater 8. Thus, the corner 34 of the stepped section 32 at which an unwanted temperature increase is more likely to occur is covered and protected by the ring plate 38 of the susceptor assembly 7.

If the whole inner area of the chamber 1 becomes extremely high, however, this may result not only in attachment of by-products to the ring plate 38 but also in deterioration of the packing materials 10 and 12, which are used to seal the flanges 9 of the chamber 1 and the flanges 11 of the gas outlets 5, respectively.

Thus, coolant water of a temperature of about 20 degrees Celsius is channeled through the coolant passageways 3a and 3b to cool the chamber 1, thereby also cooling the packing materials 10 and 12. The coolant passageways 3a and 3b serve to maintain the temperature of the deposition apparatus 50 at its suitable operating temperature while the ring plate 38 serves to prevent deposition of the silicon crystals 35 on the liner 2. It should be noted that other coolant (e.g., air) can also be used to cool the chamber 1 as long as it is capable of efficiently drawing off heat from the deposition apparatus 50.

The deposition of silicon crystal to the liner 2 can be prevented by the ring plate 38, and therefore the deposition apparatus 50 can be kept in a stabilized working condition.

The coolant to be used can include anything capable of removing heat efficiently from the deposition apparatus 50. This may include, for example, water or air.

The deposition apparatus and deposition method of the present invention solve the problem of unwanted deposition of by-products on the liner of its deposition chamber, thereby achieving less frequent maintenance and an increased apparatus operating rate. Moreover, high-quality semiconductor substrates can be manufactured due to stabilized deposition conditions.

The features and advantages of the present invention may be summarized as follows.

The above-described deposition apparatus of the present invention prevents by-products from being attached to the inner walls of the chamber during film deposition. Thus, high-quality epitaxial substrates can be manufactured.

The deposition apparatus of the present invention also makes it possible to unload the substrate and the susceptor assembly from the apparatus while the substrate is positioned on the susceptor assembly. Thus, even if by-products may be attached to the ring plate of the susceptor assembly, the assembly can be taken out of the apparatus, thereby preventing by-product accumulation inside the chamber. This in turn allows easier maintenance of the apparatus and results in an increase in the operating rate of the apparatus.

Moreover, in accordance with the deposition apparatus of the invention, the ring plate of the susceptor assembly covers the corner of the stepped section of the liner during film deposition, thereby reflecting the radiant heat from the susceptor assembly and the heater toward the substrate. The ring plate thus prevents the spread of heat away from the periphery of the substrate, thereby heating the substrate efficiently upon film deposition. As a result, the output of the heater can be reduced, making the apparatus energy-efficient.

The above-described deposition method of the invention prevents by-products from becoming attached to the inner walls of the chamber during film deposition. Thus, high-quality epitaxial substrates can be manufactured.

The deposition method of the invention also makes it possible to load the substrate and the susceptor assembly into the apparatus while the substrate is positioned on the assembly and unload the two from the apparatus after the completion of film deposition. Thus, even if by-products may be attached to the ring plate of the susceptor assembly, the assembly can be taken out of the apparatus, thereby preventing by-product accumulation inside the chamber. The unloaded susceptor assembly can then be cleaned. This allows for easier maintenance of the apparatus and results in an increase in the operating rate of the apparatus.

The present invention is not limited to the above-described embodiment but can be implemented in other various forms without departing from the scope of the invention.

While we have described the above embodiment assuming that the deposition apparatus is used for epitaxial growth, the invention is not limited thereto. The invention is applicable to any apparatus as long as it is designed to deposit a particular crystalline film on the surface of a silicon wafer. For example, the advantages of the invention can also be obtained by applying the invention to an apparatus designed to deposit polysilicon films.

The invention can also be applied to a deposition apparatus that requires a substrate to be heated at a higher temperature (e.g., 1,650 degrees Celsius) to deposit an SiC crystalline film on the surface of an SiC substrate.

While the description of the above embodiment has centered on what is directly relevant to the device configurations and control methods of the present invention, it is of course possible to make modifications thereto.

It should also be noted that the figures we have presented illustrate only those components relevant to the present invention and, for illustration purposes, do not present the actual scaling relations.

The scope of the present invention embraces any other deposition apparatus that includes the essential elements of the invention and modifications which can be made by those skilled in the art.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2010-032742, filed on Feb. 17, 2010 including specification, claims, drawings and summary, on which the Convention priority of the present application is based, are incorporated herein.

1. A deposition apparatus comprising:
a chamber;
a gas inlet for supplying a deposition gas into the chamber;
a gas outlet located at a bottom section of the chamber;
a cylindrical liner for covering inner surfaces of the chamber, the liner including: a barrel section; a head section having an opening, the head section being smaller in horizontal cross-sectional area than the barrel section; and a stepped section for connecting the barrel section and the head section;
a shower plate which operates as a flow straightening vane, located at the opening of the head section of the liner, for producing a laminar flow of the deposition gas supplied into the chamber;
a rotary shaft located at a bottom section of the chamber and extending upwardly into the barrel section of the liner;
a rotary drum connected to an upper end of the rotary shaft; and
a susceptor assembly on which to place a substrate, the susceptor assembly being supported by the rotary drum inside the barrel section,
wherein the susceptor assembly includes:
a susceptor on which to place the substrate, the susceptor being supported by the rotary drum;
support posts attached to the susceptor; and
a ring plate fixed to the support posts so that the ring plate is spaced apart from the susceptor, and
wherein the ring plate covers a peripheral area of the stepped section of the liner with the susceptor assembly being supported by the rotary drum.

2. The apparatus of claim 1, wherein a gas can exit through an area between the ring-shaped susceptor and the ring plate.

3. The apparatus of claim 1, wherein a purge gas can be fed into the space between the inner walls of the chamber and the outer walls of the liner, exiting through the area between the ring plate and the stepped section.

4. The apparatus of claim 1, wherein the susceptor assembly can be attached to and detached from the rotary drum.

5. The apparatus of claim 1, wherein the ring plate is formed from a carbon (C) material coated with at least one material selected from the group consisting of silicon carbide (SiC), tantalum carbide (TaC), and tungsten carbide (WC).

6. A deposition method for supplying a deposition gas from a top section of a chamber toward a substrate placed on a susceptor assembly supported by a rotary drum while heating the substrate, thereby depositing a particular film on the substrate,
wherein the chamber houses a cylindrical liner that includes:
a barrel section inside which the susceptor assembly is placed;
a head section smaller in horizontal cross-sectional area than the barrel section; and
a stepped section for connecting the barrel section and the head section,
wherein the susceptor assembly includes:
a susceptor on which to place the substrate;
support posts attached to the susceptor; and
a ring plate fixed to the support posts such that the ring plate is spaced from the susceptor, the ring plate being adapted to cover a peripheral area of the stepped section of the liner, and
wherein the deposition gas flows inside the head section of the liner and moves in a downward direction toward the substrate.

7. The method of claim 6, wherein a gas can exit through an area between the susceptor and the ring plate after thermal decomposition or hydrogen reduction on to the substrate.

8. The method of claim 6, wherein a purge gas can be fed into the space between the inner walls of the chamber and the outer walls of the liner, the purge gas can then exit through the area between the ring plate and the stepped section.

9. The method of claim 6 comprising the steps of:
placing the substrate on the susceptor assembly outside of the chamber;
attaching the susceptor assembly on which the substrate has been placed to the rotary drum, thereby loading the susceptor assembly and the substrate into the chamber; and
detaching the susceptor assembly from the rotary drum while the substrate is positioned on the susceptor assembly after deposition of a particular film on the substrate, thereby unloading the susceptor assembly and the substrate from the chamber.

10. The method of claim 1 or 2, wherein the ring plate is formed from a carbon (C) material coated with at least one material selected from the group consisting of silicon carbide (SiC), tantalum carbide (TaC), and tungsten carbide (WC).
